(19) United States
(12) Patent Application Publication
(10) Pub. No.: US 2004/0178057 A1
(43) Pub. Date: Sep. 16, 2004

(54) Method of manufacturing electrode plate for battery

(76) Inventors: Charles Leu, Fremont, CA (US); Ga-Lane Chen, Fremont, CA (US); Ming-Hsuan Liu, Tu-Chen (TW); Chuan-De Huang, Tu-chen (TW); Chang-Chih Sung, Tu-Chen (TW); Tai-Cheng Yu, Tu-Chen (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/683,014

(22) Filed: Oct. 9, 2003

(30) Foreign Application Priority Data
Mar. 14, 2003 (TW) 92105709

(51) Int. Cl. C23C 14/32

(52) U.S. Cl. 204/192.15; 204/298.13

(57) ABSTRACT

A method of manufacturing an electrode plate (2) for a battery includes the steps of: preparing a substrate (21) and a target (4), the target being made from an active material, and respectively mounting the substrate and the target in a sputtering chamber (1)a predetermined distance apart; evacuating the sputtering chamber; introducing a non-reactive gas and a reactive gas into the sputtering chamber; applying a voltage between the target and the substrate using a power source (5), thus activating a plasma between the target and the substrate and resulting in deposit of the active material from the target on the substrate until a desired thickness of an active material layer (22) is formed on the substrate.

### BACKGROUND OF THE INVENTION

1. Field of the Invention

The present invention relates to a method of manufacturing an electrode plate, and particularly to a method of manufacturing an electrode plate for a battery.

2. Description of Related Art

An electrode plate normally includes a substrate and an active material layer attached thereon. For instance, an anode plate of a lithium battery includes a current collector and an active material layer containing lithium attached on the current collector. The conventional method of manufacturing an anode plate of a lithium battery comprises the steps of: blending selected active materials, such as LiCoO₂, together with an organic adhesive and an organic solvent; covering a prepared current collector with the blending; then drying the covered current collector, thus obtaining a desired anode plate. A similar method is disclosed in a Chinese patent application having publication No. 1275818A. Referring to this reference, a method of manufacturing an anode plate of a lithium battery comprises the steps of: blending active materials together with a polyvinyl chloride adhesive, a conductive additive, and a solvent; coating a current collector with the blending; and drying the coated current collector in a temperature range of 80 to 150 degrees centigrade. However, a uniform concentration of the active materials can not be formed in the coating on the current collector since a transference phenomenon of the active materials occurs during drying of the coating, which affects the electric capability of the electrode, and can even cause malfunctions of the battery. Furthermore, an adherence between the coating of active materials and the current collector is not strong, and so the coating may be easily peeled off from the current collector. Additionally, use of the adhesive, conductive additive, and solvent results in environmental pollution.

Therefore, an improved method of manufacturing an electrode plate for a battery is desired which overcomes the disadvantages of the prior art.

### SUMMARY OF THE INVENTION

A main object of the present invention is to provide a reliable, safe method of manufacturing an electrode plate for a battery, wherein the active material layer of the electrode plate has a uniform concentration and strongly adheres to the substrate of the electrode plate.

A method of manufacturing an electrode plate for a battery comprises the steps of: preparing a substrate and a target, the target being made from an active material, and respectively mounting the substrate and the target in a sputtering chamber a predetermined distance apart; evacuating the sputtering chamber to a predetermined degree of vacuum; introducing non-reactive gas and reactive gas into the sputtering chamber to a predetermined gas pressure level; applying a voltage to the target using a power source, thus activating a plasma between the target and the substrate and resulting in deposit of the active material from the target on the substrate until a desired thickness of an active material layer is formed on the substrate.

Other objects, advantages and novel features of the invention will become more apparent from the following detailed description of a preferred embodiment thereof when taken in conjunction with the accompanying drawings, wherein:

### BRIEF DESCRIPTION OF THE DRAWINGS

FIG. 1 is a side view of an electrode plate in accordance with a preferred embodiment of the present invention; and

FIG. 2 is a schematic diagram of an arrangement for manufacturing the electrode plate of FIG. 1.

### DETAILED DESCRIPTION OF THE INVENTION

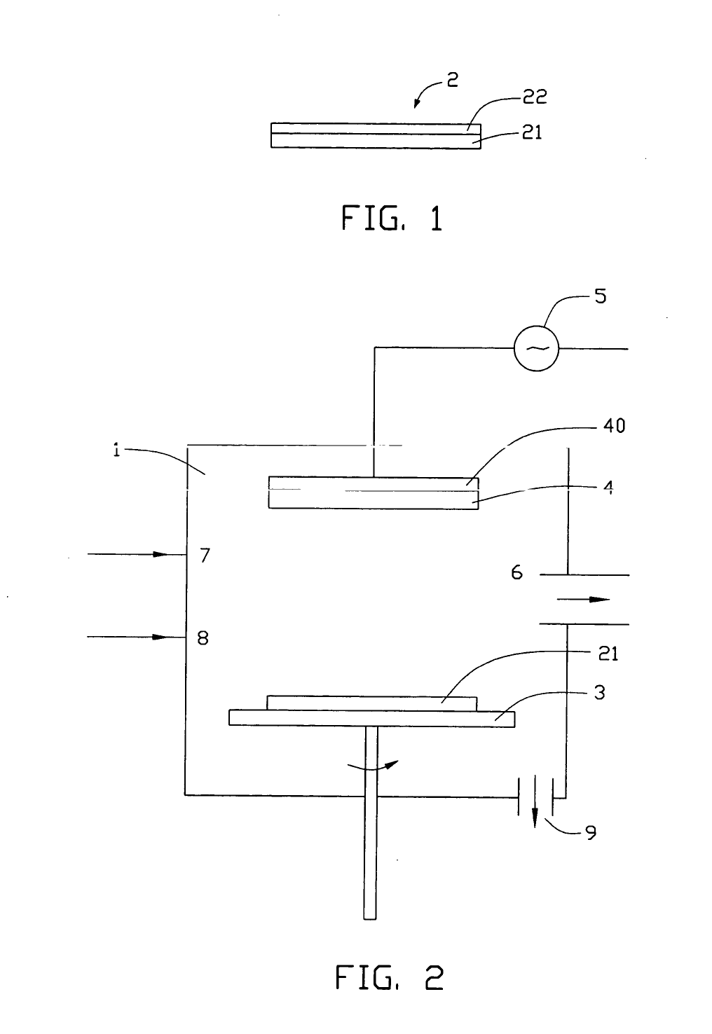

Referring now to the drawings in detail, FIG. 1 shows an electrode plate 2 in accordance with a preferred embodiment of the present invention. The electrode plate 2 comprises a substrate 21 and an active material layer 22 bonded to the substrate 21. In this embodiment, the electrode plate 2 is an anode plate of a rechargeable lithium battery, and the substrate 21 is a current collector made of aluminum. The active material is an oxide of lithium, such as LiNiO₂, LiNiCoₓO₂ (0<×<1), LiMnO₂, LiₓCo_{1-y}Al_{y}O2, LiCoO₂, LiMn₂O₄, LiₓNi_{1-y-z}Co_{y}Al_{z}O₂ and so on. The active material can also be a sulfide of lithium, a fluoride of lithium, a carbide of lithium, a phosphide of lithium, or a composite formed from a polyaniline derivative. In this embodiment, we choose LiNi_{0.8}Co_{0.15}Al_{0.05}O₂ as the active material to describe the method of the present invention in detail.

Referring to FIG. 2, an arrangement for manufacturing the electrode plate 2 has a sputtering chamber 1. The sputtering chamber 1 has a holder 40 and a rotary support 3 therein, a vacuum port 6 connecting to an outer vacuum system (not shown), gas inlets 7, 8 and an outlet 9. The method of manufacturing the electrode plate 2 comprises the steps of:

(1) preparing the substrate 21 and a target 4, and respectively mounting the substrate 21 on the rotary support 3, and the target 4 on the holder 40 in the chamber la predetermined distance apart;

(2) evacuating the sputtering chamber 1 to a predetermined degree of vacuum using the vacuum port 6 and the vacuum system;

(3) introducing non-reactive gas and reactive gas into the sputtering chamber 1 to a predetermined gas pressure level through the gas inlets 7, 8;

(4) applying a voltage to the target 4 using a power source 5, thus activating a plasma between the target 4 and the substrate 21 and depositing the active resulting active material layer 22 is achieved on the substrate 21.

In the first step, the active material, LiNi_{0.8}Co_{0.15}Al_{0.05}O₂, and the target 4, made from the active material LiNi_{0.8}Co_{0.15}Al_{0.05}O₂, are sequentially prepared using known processes in the art. The substrate 21, which is a current collector, is made of aluminum using a conventional process. The target 4 is mounted on the holder 40 and connects with the power source 5 through a switch (not shown). At this time, the switch is open. The substrate 21 is mounted on the rotary support 3 and can be rotated, thus the substrate 21 can be uniformly deposited. The target 4 is used as one electrode and is maintained at an applied voltage, and the substrate 21 is used as the other electrode and is grounded during the sputtering process.

After the target 4 and the substrate 21 are mounted in the sputtering chamber 1, the sputtering chamber 1 is evacuated by means of the vacuum port 6 and the vacuum system (not shown) until the level of vacuum therein is between 10⁻⁸ and 10⁻⁶ Torr. Subsequently, the non-reactive gas and the reactive gas are introduced into the sputtering chamber 1 respectively through the gas inlets 7, 8. The reactive gas contains the element or elements of which the active material layer is made. In this embodiment, the non-reactive gas is argon, and the reactive gas is oxygen. It is understood that other non-reactive gas and reactive gas can be used if desired. A flow rate of argon is controlled between 5 and 50 SCCM (Standard Cubic Centimeter per Minute), a flow rate of oxygen is controlled between 1 and 15 SCCM, and the gas pressure in the chamber 1 is maintained in the range of 10⁻⁵ to 10 Torr during the sputtering process. When the pressure in the chamber 1 gets to a predetermined value, the switch is closed, thus applying voltage between the target 4 and the substrate 21 through the power source 5. As a consequence, a plasma is activated between the target 4 and the substrate 21, argon and oxygen atoms are ionized, and positively charged ions of argon are accelerated to the target 4, striking it with sufficient energy to cause the ejection of atoms of the active material from the target 4 and deposition on the substrate 21. In this embodiment of the present invention, the power source 5 is an RF power source, and the power level applied to the target 4 may be in the range of 100 to 250 W. During the sputtering and deposition of the active material, the ejected atoms of the active material combine with the oxygen ions for stoichoimetric deposit of the LiNi_{0.8}Co_{0.15}Al_{0.05}O₂ layer 22 on the substrate 21. If no reactive gas, i.e., no oxygen, is introduced into the chamber 1, a less than stoichoimetric deposit of the active material will result, and the formed layer 22 will be chemically unstable.

When the layer 22 is deposited to the predetermined thickness, the switch is opened, shutting off the sputtering process. Residual gas is expelled from in the chamber 1, until the temperature in the chamber 1 reaches room temperature. Then the deposited substrate 21 is taken out of the chamber 1. Finally, the desired electrode plate 2 of the present invention is obtained.

In other embodiments, direct or alternating current power may be applied to the target 4 through the power source 5. Furthermore, a microwave power source can instead be used as the power source 5, or a magnetic field perpendicular to the electric field generated by the power source 5 may be created by means of a permanent magnet or an electromagnet, for the purpose of enhancing the ionization of the plasma gases and the ejection of the active material, thus accelerating the deposition speed of the layer 22.

It is also possible to make the active material layer 22 out of other active materials to form different electrode plates of batters using appropriate targets and feeding with appropriate reactive gases.

In the sputtering process described above for deposition of the active material layer 22 onto the substrate 21, atoms ejected from the target 4 travel to and strike the substrate 21 and are deposited thereon a substantially uniform layer. In the interface between the layer 22 and the substrate 21, atoms of the active material are inserted into the inner configuration of the substrate 21, whereby, a good adhesion of the layer 22 to the surface of the substrate 21is acquired. Furthermore, since no adhesive, conductive additive or solvent is used in the method of the present invention, it is more reliable and safer for the operator to use this method to manufacture the electrode plate 2.

It is understood that the invention may be embodied in other forms without departing from the spirit thereof. Thus, the present examples and embodiments are to be considered in all respects as illustrative and not restrictive, and the invention is not to be limited to the details given herein.

What is claimed is:

1. A method of manufacturing an electrode plate for a battery comprising the steps of:
(1) preparing a substrate and a target, the target being made from at least one active material, and respectively mounting the substrate and the target in a sputtering chamber a predetermined distance apart;
(2) evacuating the sputtering chamber to a predetermined degree of vacuum;
(3) introducing non-reactive gas and reactive gas into the sputtering chamber to a predetermined gas pressure level;
(4) applying a voltage to the target using a power source, thus activating a plasma between the target and the substrate and resulting in deposit of the active material from the target on the substrate until a layer of a desired thickness of the active material is formed on the substrate.

2. The method as claimed in claim 1, wherein said reactive gas contains an element or elements of which said active material layer is made.

3. The method as claimed in claim 1, wherein said degree of vacuum is to be controlled in the range of 10⁻⁸ to 10⁻⁶ Torr.

4. The method as claimed in claim 1, wherein said gas pressure level is maintained in the range of 10⁻⁵ to 10 Torr.

5. The method as claimed in claim 1, wherein a flow rate of said non-reactive gas is controlled to be between 5 and 50 SCCM, and a flow rate of said reactive gas is controlled to be between 1 and 15 SCCM.

6. The method as claimed in claim 1, wherein said power source is an RF power source, a direct current power source, or an alternating current power source, or a microwave power source.

7. The method as claimed in claim 6, wherein a magnetic field is created perpendicular to the electric field created by the power source in the sputtering chamber for improving the deposition process of the active material.

8. The method as claimed in claim 6, wherein a power level applied to the target by the power source is in the range of 100 to 250 W.

9. The method as claimed in claim 1, wherein said battery is a lithium battery.

10. The method as claimed in claim 9, wherein said active material is an oxide of lithium, a sulfide of lithium, a fluoride of lithium, a carbide of lithium, a phosphide of lithium, or a composite formed from a polyaniline derivative.

11. The method as claimed in claim 9, wherein said substrate is a current collector.

12. The method as claimed in claim 11, wherein said current collector is made of aluminum.

13. A system for making an electrode plate for a battery, comprising:
a vacuum chamber;
a target essentially consisting active material including lithium, said target
disposed in the chamber and functioning as an electrode;
a substrate disposed in the chamber and functioning as the other electrode;
a power source activating plasmas, derived from the target, to be deposited on
the substrate via a sputtering procedure; and
reactive gas and non-reactive gas passing the chamber; wherein said reactive
gas is to supplement some elements of said active material consumed during
deposition of said active material on said substrate.

14. The system as claimed in claim 13, wherein said substrate with deposited active material thereon is essentially of a positive electrode plate of the battery.
